(19) United States
(12) Patent Application Publication
(10) Pub. No.: US 2016/0138186 A1
(43) Pub. Date: May 19, 2016

(54) SILICON CARBIDE SINGLE-CRYSTAL SUBSTRATE AND METHOD OF MANUFACTURING THE SAME

(71) Applicant: SUMITOMO ELECTRIC INDUSTRIES, LTD., Osaka-shi, Osaka (JP)

(72) Inventors: Tsutomu HORI, Itami-shi (JP); Tomohiro KAWASE, Itami-shi (JP); Makoto SASAKI, Itami-shi (JP)

(21) Appl. No.: 14/898,527

(22) PCT Filed: May 14, 2014
(86) PCT No.: PCT/JP2014/062837

§ 371 Date: Dec. 15, 2015

(30) Foreign Application Priority Data
Jul. 3, 2013 (JP) 2013-139771

(51) Int. Cl. C30B 23/02; C30B 29/36

(52) U.S. Cl. CPC C30B 23/025; C30B 29/36

(57) ABSTRACT

A method of manufacturing a silicon carbide single-crystal substrate includes the following steps. A seed crystal having a main surface and being made of silicon carbide, and a silicon carbide source material are prepared. A silicon carbide single crystal is grown on the main surface by sublimating the silicon carbide source material while maintaining a temperature gradient between any two points in the silicon carbide source material at 30° C./cm or less. The main surface of the seed crystal is a {0001} plane or a plane having an off angle of 10° or less relative to the {0001} plane, and the main surface has a screw dislocation density of 20/cm² or more. Thus, a silicon carbide single-crystal substrate capable of achieving improved crystal quality and a method of manufacturing the same are provided.

### TECHNICAL FIELD

The present invention relates to silicon carbide single-crystal substrates and methods of manufacturing the same, and more specifically to a silicon carbide single-crystal substrate capable of achieving improved crystal quality and a method of manufacturing the same.

### BACKGROUND ART

In recent years, silicon carbide has been increasingly employed as a material for a semiconductor device such as a MOSFET (Metal Oxide Semiconductor Field Effect Transistor) in order to allow a higher breakdown voltage, lower loss, the use in a high-temperature environment and the like of the semiconductor device. Silicon carbide is a wide band gap semiconductor having a band gap wider than that of silicon which has been conventionally and widely used as a material for a semiconductor device. By employing the silicon carbide as a material for a semiconductor device, therefore, a higher breakdown voltage, lower on-resistance and the like of the semiconductor device can be achieved. A semiconductor device made of silicon carbide is also advantageous in that performance degradation is small when used in a high-temperature environment as compared to a semiconductor device made of silicon.

For example, Japanese Patent Laying-Open No. 2001-294499 (PTD 1) discloses an example of methods of manufacturing a silicon carbide single crystal. According to this publication, when growing a silicon carbide single crystal with a sublimation-recrystallization method, a crucible is designed and growth conditions are selected such that a temperature gradient in the grown crystal is 15° C. or less at all times during the growth, thereby manufacturing a silicon carbide single-crystal wafer in which the difference from a (0001) plane orientation between any two points in a wafer surface is 40 sec/cm or less.

Japanese Patent Laying-Open No. 2010-235390 (PTD 2) states that when a silicon carbide single crystal is grown on a growth surface using a dislocation-controlled seed crystal, a high-density screw dislocation is introduced in a c-plane facet. It is stated that the occurrence of a different polytype or different orientation crystal is thus suppressed on the c-plane facet, thereby providing a homogeneous silicon carbide single crystal having a low defect density.

Further, Japanese Patent Laying-Open No. 5-262599 (PTD 3) describes using a seed crystal having an exposed face deviating from a {0001} plane by an angle of about 60° to about 120° when producing a silicon carbide single crystal by sublimation. It is stated that a silicon carbide single crystal without other polytypes mixed therein is thus grown.

### CITATION LIST

### Patent Documents

PTD 1: Japanese Patent Laying-Open No. 2001-294499

PTD 2: Japanese Patent Laying-Open No. 2010-235390

PTD 3: Japanese Patent Laying-Open No. 5-262599

### SUMMARY OF INVENTION

### Technical Problem

If a temperature gradient in a silicon carbide single crystal is simply set to 15° C./cm or less as described in Japanese Patent Laying-Open No. 2001-294499, however, a different polytype may occur, and the crystal quality of the silicon carbide single crystal cannot be improved sufficiently. If a screw dislocation is simply introduced in a c-plane facet as described in Japanese Patent Laying-Open No. 2010-235390, a plane orientation difference in the plane cannot be reduced, and the crystal quality of a silicon carbide single crystal cannot be improved sufficiently. Further, if a seed crystal having an exposed face deviating from a {0001} plane by an angle of about 60° to about 120° is used as described in Japanese Patent Laying-Open No. 5-262599, a stacking fault occurs in a silicon carbide single crystal to degrade the crystal quality of the silicon carbide single crystal.

The present invention has been made to solve the problems as described above, and an object of the present invention is to provide a silicon carbide single-crystal substrate capable of achieving improved crystal quality and a method of manufacturing the same.

### Solution to Problem

A method of manufacturing a silicon carbide single-crystal substrate according to the present invention includes the following steps. A seed crystal having a main surface and being made of silicon carbide, and a silicon carbide source material are prepared. A silicon carbide single crystal 1 is grown on the main surface by sublimating the silicon carbide source material while maintaining a temperature gradient between any two points in the silicon carbide source material at 30° C./cm or less. The main surface of the seed crystal is a {0001} plane or a plane having an off angle of 10° or less relative to the {0001} plane, and the main surface has a screw dislocation density of 20/cm² or more.

A silicon carbide single-crystal substrate according to the present invention has a main surface. The main surface has a maximum dimension of 100 mm or more. A {0001} plane orientation difference between any two points spaced apart from each other by 1 cm in the main surface is 35 seconds or less.

### Advantageous Effects of Invention

According to the present invention, a silicon carbide single-crystal substrate capable of achieving improved crystal quality and a method of manufacturing the same can be provided.

### BRIEF DESCRIPTION OF DRAWINGS

FIG. 1 is a schematic perspective view schematically illustrating a structure of a silicon carbide single-crystal substrate according to one embodiment of the present invention.

FIG. 2 is a schematic sectional view schematically illustrating the structure of the silicon carbide single-crystal substrate according to the embodiment of the present invention.

FIG. 3 is a schematic plan view schematically illustrating the structure of the silicon carbide single-crystal substrate according to the embodiment of the present invention.

FIG. 4 is a flowchart schematically illustrating a method of manufacturing the silicon carbide single-crystal substrate according to the embodiment of the present invention.

FIG. 5 is a schematic sectional view schematically illustrating a structure of a device of manufacturing the silicon carbide single-crystal substrate according to the embodiment of the present invention.

FIG. 6 is a schematic sectional view schematically illustrating the method of manufacturing the silicon carbide single-crystal substrate according to the embodiment of the present invention.

FIG. 7 is a schematic sectional view conceptually illustrating the spiral growth of a silicon carbide single crystal.

FIG. 8 is a schematic perspective view conceptually illustrating the spiral growth of a silicon carbide single crystal.

FIG. 9 is a schematic sectional view illustrating a first step for measuring a temperature gradient in a silicon carbide source material.

FIG. 10 is a schematic sectional view illustrating a second step for measuring the temperature gradient in the silicon carbide source material.

FIG. 11 is a schematic sectional view illustrating a third step for measuring the temperature gradient in the silicon carbide source material.

FIG. 12 is a schematic sectional view illustrating a fourth step for measuring the temperature gradient in the silicon carbide source material.

### DESCRIPTION OF EMBODIMENTS

An embodiment of the present invention will be described below with reference to the drawings. In the following drawings, the same or corresponding parts are designated by the same reference numbers and description thereof will not be repeated. Regarding crystallographic denotation herein, an individual orientation, a group orientation, an individual plane, and a group plane are shown in [ ], < >, ( ) and { }, respectively. Although a crystallographically negative index is normally expressed by a number with a bar “−” thereabove, a negative sign herein precedes a number to indicate a crystallographically negative index. In expressing an angle, a system in which a total azimuth angle is defined as 360 degrees is employed.

A summary of the embodiment of the present invention will be described first.

The inventors made the following findings as a result of a diligent study on a method of manufacturing a silicon carbide single crystal of excellent crystal quality, and conceived of the present invention.

During silicon carbide crystal growth, a stacked structure of a seed crystal is transferred to the grown crystal in two growth modes of step-flow growth and spiral growth. The spiral growth occurs mainly in a facet portion, and uses a screw dislocation as a supply source of information on the stacked structure. When the screw dislocation density is low, therefore, a crystal structure of the seed crystal cannot be adequately transferred to the grown crystal, thus increasing the occurrence of a different polytype in the facet portion of a growth surface of the grown crystal. In other words, in order to suppress the occurrence of a different polytype, a main surface of the seed crystal needs to have a screw dislocation of a certain density. Particularly in order to manufacture a silicon carbide single-crystal substrate having a large diameter of 100 mm or more while suppressing the occurrence of a different polytype, the screw dislocation density in a main surface of a seed crystal needs to be controlled such that it is higher than or equal to a certain density. In addition, in order to reduce a plane orientation difference in a silicon carbide single-crystal substrate having a diameter of 100 mm or more, a temperature distribution in a silicon carbide source material needs to be controlled such that it is smaller than or equal to a certain temperature gradient.

As a result of a diligent study, the inventors found that, by using a seed crystal having a screw dislocation density of 20/cm² or more in a main surface thereof, and by growing a silicon carbide single crystal on the main surface of the seed crystal by sublimating a silicon carbide source material while maintaining a temperature gradient between any two points in the silicon carbide source material at 30° C./cm or less, a silicon carbide single-crystal substrate can be manufactured in which a {0001} plane orientation difference between any two points spaced apart from each other by 1 cm in a main surface of the silicon carbide single-crystal substrate is 35 seconds or less, in which the mixture of a different polytype can be suppressed, and in which the main surface has a maximum dimension of 100 mm or more to provide a large diameter.

(1) A method of manufacturing a silicon carbide single-crystal substrate 10 according to this embodiment includes the following steps. A seed crystal 2 having a main surface 2a and being made of silicon carbide, and a silicon carbide source material 3 are prepared. A silicon carbide single crystal 1 is grown on main surface 2a by sublimating silicon carbide source material 3 while maintaining a temperature gradient between any two points in silicon carbide source material 3 at 30° C./cm or less. Main surface 2a of seed crystal 2 is a {0001} plane or a plane having an off angle of 10° or less relative to the {0001} plane, and main surface 2a has a screw dislocation density of 20/cm² or more.

According to the method of manufacturing silicon carbide single-crystal substrate 10 of this embodiment, silicon carbide single-crystal substrate 10 can be manufactured in which a {0001} plane orientation difference between any two points spaced apart from each other by 1 cm in a main surface 10a is 35 seconds or less, in which the mixture of a different polytype can be suppressed, and in which main surface 10a has a maximum dimension of 100 mm or more.

(2) Preferably, in the method of manufacturing silicon carbide single-crystal substrate 10 of this embodiment, main surface 2a has a screw dislocation density of 100000/cm² or less. Thus, the screw dislocation density in main surface 10a of silicon carbide single-crystal substrate 10 can be lowered.

(3) Preferably, in the method of manufacturing silicon carbide single-crystal substrate 10 of this embodiment, in the step of growing silicon carbide single crystal 1, a temperature gradient between a surface 3a of silicon carbide source material 3 and a growth surface 1a of silicon carbide single crystal 1 facing surface 3a of silicon carbide source material 3 is 5° C./cm or more. Thus, a growth rate of silicon carbide single crystal 1 can be improved.

(4) Preferably, in the method of manufacturing silicon carbide single-crystal substrate 10 of this embodiment, main surface 2a of seed crystal 2 has a maximum dimension of 80 mm or more, a cut surface of silicon carbide single crystal 1 sliced along a plane parallel to main surface 2a has a maximum dimension of 100 mm or more, and the maximum dimension of the cut surface of silicon carbide single crystal 1 is greater than the maximum dimension of main surface 2a of seed crystal 2. Thus, silicon carbide single-crystal substrate 10 including main surface 10a having a great dimension can be manufactured.

(5) Silicon carbide single-crystal substrate 10 according to this embodiment has a main surface 10a. Main surface 10a has a maximum dimension of 100 mm or more. A {0001} plane orientation difference between any two points spaced apart from each other by 1 cm in main surface 10a is 35 seconds or less. Thus, silicon carbide single-crystal substrate 10 can be provided in which main surface 10a has a maximum dimension of 100 mm or more, and which has an excellent crystal quality.

(6) Preferably, in silicon carbide single-crystal substrate 10 of this embodiment, main surface 10a has a screw dislocation density of 20/cm² or more and 100000/cm² or less. Thus, silicon carbide single-crystal substrate 10 having a lowered screw dislocation density in main surface 10a can be provided.

The embodiment of the present invention will now be described in more detail.

First, a structure of a silicon carbide single-crystal substrate according to this embodiment will be described with reference to FIGS. 1 to 3.

Referring to FIG. 1, a silicon carbide single-crystal substrate 10 according to this embodiment is made of hexagonal silicon carbide having a polytype of 4H, for example, and has a first main surface 10a, and a second main surface 10b opposite to first main surface 10a. A maximum dimension D1 of the diameter of silicon carbide single-crystal crystal substrate 10 is 100 mm or more, for example, and preferably 150 mm or more. First main surface 10a of silicon carbide single-crystal substrate 10 is, for example, on average, a {0001} plane or a plane having an off angle of 10° or less relative to the {0001} plane. Specifically, the first main surface may be, for example, a (0001) plane or a plane having an off angle of about 10° or less relative to the (0001) plane, or may be a (000-1) plane or a plane having an off angle of about 10° or less relative to the (000-1) plane.

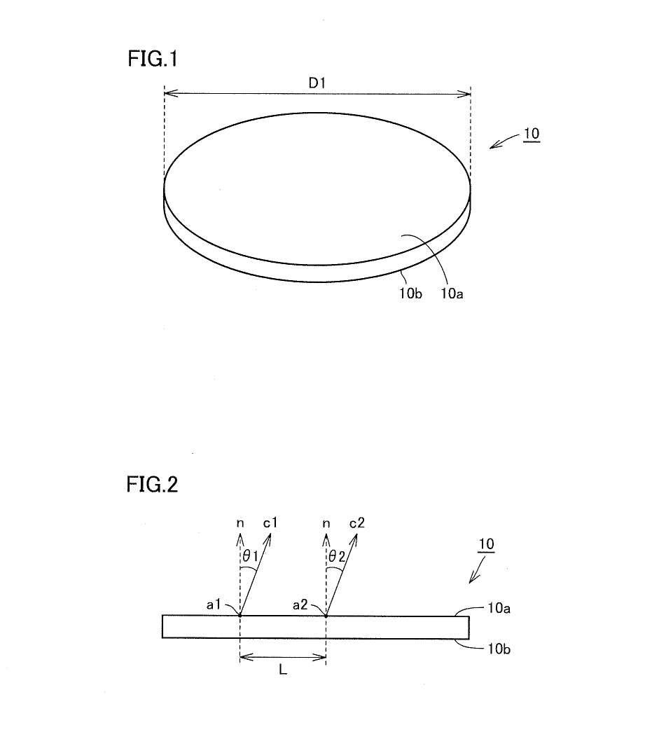

Referring to FIG. 2, a {0001} plane orientation difference in first main surface 10a of silicon carbide single-crystal substrate 10 is described. As is illustrated in FIG. 1 of Japanese Patent Laying-Open No. 2001-294499, a detailed observation of a portion in the vicinity of first main surface 10a of silicon carbide single-crystal substrate 10 shows that silicon carbide single-crystal substrate 10 is formed of a large number of domains minutely different from one another in plane orientation. That is, even when first main surface 10a of silicon carbide single-crystal substrate 10 is, on average, the {0001} plane, a {0001} plane orientation at each position in the plane of first main surface 10a minutely deviates from a normal direction n of first main surface 10a.

As shown in FIG. 2, a {0001} plane orientation c1 at any position al in first main surface 10a deviates in one direction by an angle θ1 from normal direction n of first main surface 10a. A {0001} plane orientation c2 at a position a2 in first main surface 10a spaced apart from any position al in first main surface 10a by a length L deviates in one direction by an angle θ2 from normal direction n of first main surface 10a. Length L is 1 mm, for example. In this embodiment, the {0001} plane orientation difference refers to an absolute value of the difference between the aforementioned angle θ1 and the aforementioned angle θ2. The {0001} plane orientation difference between any two points spaced apart from each other by 1 cm in first main surface 10a of silicon carbide single-crystal substrate 10 is 35 seconds or less, and more specifically, a (0001) plane orientation difference between any two points spaced apart from each other by 1 cm in first main surface 10a is 35 seconds or less. Preferably, the {0001} plane orientation difference between any two points spaced apart from each other by 1 cm in first main surface 10a is 30 seconds or less, and more preferably, the {0001} plane orientation difference is 25 seconds or less. Preferably, first main surface 10a of silicon carbide single-crystal substrate 10 has a screw dislocation density of 20/cm² or more and 100000/cm² or less. The screw dislocation density in first main surface 10a of silicon carbide single-crystal substrate 10 can be measured, for example, by performing etching in which a wafer is immersed for five minutes in molten potassium hydroxide that has been heated to 520° C., and counting the number of etch pits generated.

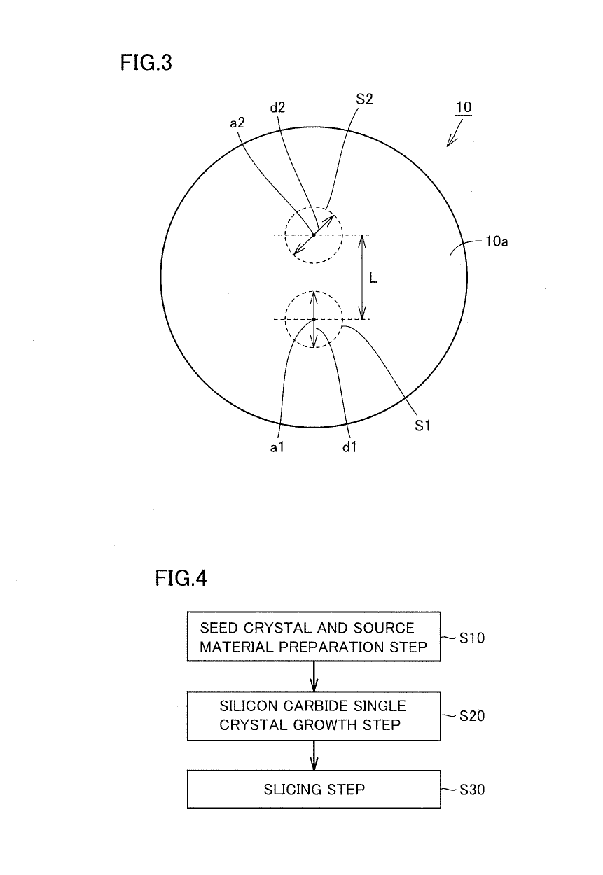

Referring to FIG. 3, a method of measuring a plane orientation difference is described. A plane orientation difference at any position in first main surface 10a can be measured, for example, via X-ray diffraction, X-ray topography or the like. Cu-Kα1 is used, for example, as an X-ray source, and (0004) peak is measured. A wavelength is 1.5405 angstroms (monochromatization). For example, a {0001} plane orientation at position al in first main surface 10a is measured with an X-ray. Spot diameters d1 and d2 of the X-ray is, for example, about 1 mm or more and 7 mm or less, and is 3 mm, for example. When measuring the {0001} plane orientation at position al in first main surface 10a, for example, an adjustment is made such that the center of a spot S1 of the X-ray is located at position al. Likewise, when measuring a {0001} plane orientation at any position a2 in first main surface 10a spaced apart from position a1 in first main surface 10a by 1 mm, an adjustment is made such that the center of a spot S2 of the X-ray is located at position a2. In other words, the any two points spaced apart from each other by 1 cm in first main surface 10a mean that the center of first spot S1 and the center of second spot S2 of the X-ray are spaced apart from each other by 1 cm. The plane orientation at each of the any two points spaced apart from each other by 1 cm in first main surface 10a of silicon carbide single-crystal substrate 10 is measured in this manner, and the {0001} plane orientation difference between the two points is calculated.

Referring to FIG. 4, a method of manufacturing the silicon carbide single-crystal substrate according to this embodiment is described.

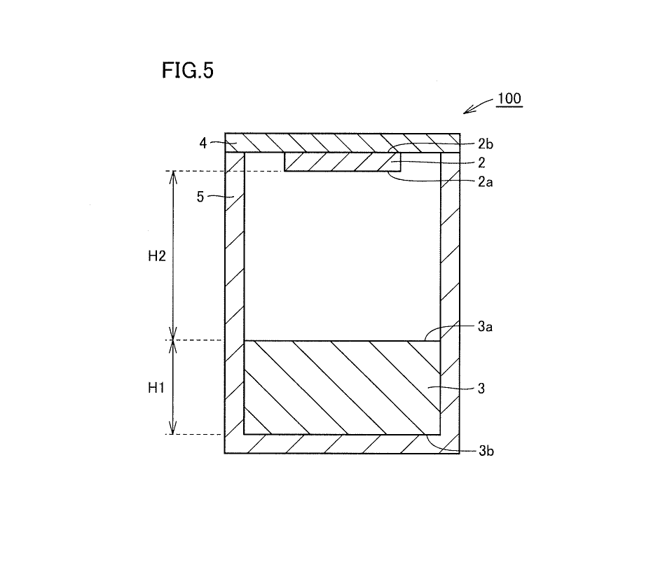

First, a silicon carbide single crystal manufacturing device 100 is prepared. Referring to FIG. 5, silicon carbide single crystal manufacturing device 100 according to this embodiment has a crucible and a heating unit (not shown). The crucible is made of graphite, for example, and has a seed crystal holding unit 4 and a source material containing unit 5. Seed crystal holding unit 4 is configured to be able to hold seed crystal 2 made of single-crystal silicon carbide. Source material containing unit 5 is configured such that a silicon carbide source material 3 made of polycrystalline silicon carbide can be placed therein. The crucible has an outer diameter of about 160 mm, for example, and an inner diameter of about 120 mm, for example. The heating unit is an induction heating heater or a resistance heating heater, for example, and is disposed to surround the outer circumference of the crucible. The heating unit is configured to be able to raise the temperature of the crucible to a sublimation temperature of silicon carbide.

Next, a seed crystal and source material preparation step (S10: FIG. 4) is performed. Specifically, referring to FIG. 5, seed crystal 2 made of hexagonal silicon carbide having a polytype of 4H, for example, is fixed to seed crystal holding unit 4. Seed crystal 2 has a first main surface 2a, and a second main surface 2b opposite to first main surface 2a. Second main surface 2b of seed crystal 2 is in contact with and held by seed crystal holding unit 4. Silicon carbide source material 3 is contained in source material containing unit 5. Silicon carbide source material 3 is made of polycrystalline silicon carbide, for example. Silicon carbide source material 3 is placed in source material containing unit 5 such that first main surface 2a of seed crystal 2 faces a surface 3a of silicon carbide source material 3. In this manner, seed crystal 2 having first main surface 10a and being made of silicon carbide, and silicon carbide source material 3 are prepared. Seed crystal 2 and silicon carbide source material 3 are placed in the crucible such that a height H1 from surface 3a to a rear surface 3b of silicon carbide source material 3 is 20 mm, for example, and a height H2 from surface 3a of silicon carbide source material 3 to first main surface 2a of seed crystal 2 is about 100 mm.

First main surface 2a of seed crystal 2 has a maximum dimension of 80 mm or more, for example, and preferably 100 mm or more. First main surface 2a of seed crystal 2 is, for example, the {0001} plane or a plane having an off angle of about 10° or less relative to the {0001} plane. Preferably, first main surface 2a of seed crystal 2 is a plane having an off angle of about 10° or less relative to the (0001) plane, and more preferably a plane having an off angle of about 4° or less relative to the (0001) plane. First main surface 2a of seed crystal 2 has a screw dislocation density of 20/cm² or more, preferably 500/cm² or more, and more preferably 1000/cm² or more. Preferably, first main surface 2a of seed crystal 2 has a screw dislocation density of 100000/cm² or less.

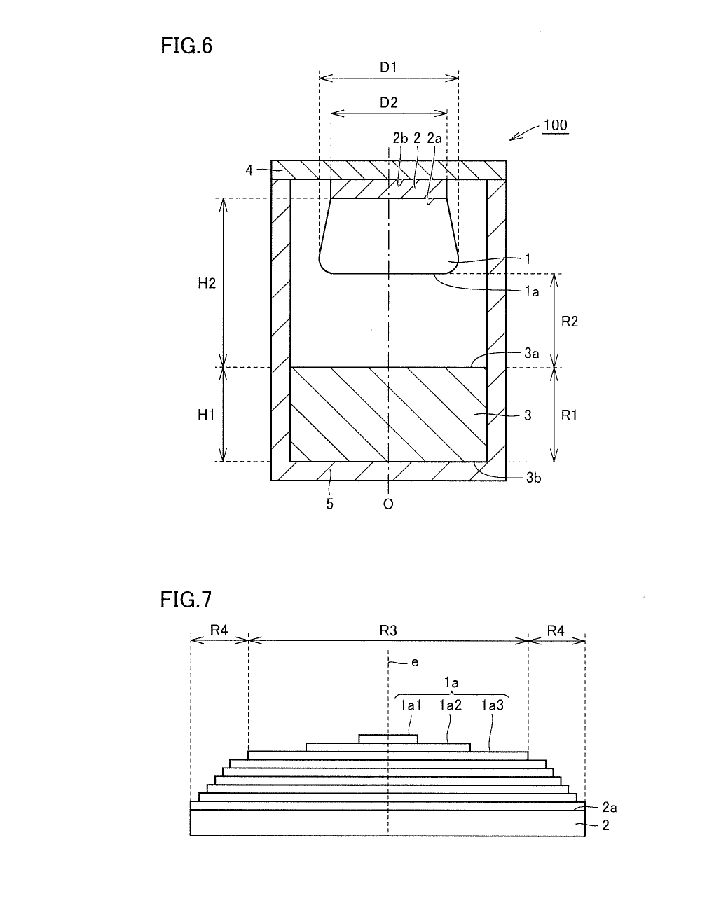

Next, a silicon carbide single crystal growth step (S20: FIG. 4) is performed. Specifically, referring to FIG. 6, the crucible containing silicon carbide source material 3 and seed crystal 2 is heated in an atmospheric gas containing helium gas and nitrogen gas, for example, from ordinary temperature to a temperature at which a silicon carbide crystal is sublimated (2300° C., for example). The heating is performed such that seed crystal 2 has a temperature lower than that of silicon carbide source material 3. That is, the crucible is heated such that the temperature decreases in a direction from silicon carbide source material 3 toward seed crystal 2. Then, a pressure in the crucible is lowered to 1 kPa, for example. This causes sublimation of silicon carbide source material 3 in the crucible and recrystallization of the material on first main surface 2a of seed crystal 2, whereby a silicon carbide single crystal 1 starts to grow on first main surface 2a of seed crystal 2. The growth of silicon carbide single crystal 1 is conducted for about 100 hours, for example. In this manner, silicon carbide single crystal 1 grows on first main surface 2a of seed crystal 2.

In the step of growing the silicon carbide single crystal, silicon carbide single crystal 1 may be grown such that maximum dimension D1 of silicon carbide single crystal 1 along a direction parallel to first main surface 2a of seed crystal 2 is greater than a maximum dimension D2 of first main surface 2a of seed crystal 2. Maximum dimension D1 of silicon carbide single crystal 1 along the direction parallel to first main surface 2a of seed crystal 2 may be 100 mm or more, and maximum dimension D2 of first main surface 2a of seed crystal 2 may be 80 mm or more. In addition, silicon carbide single crystal 1 grown by the crystal growth of silicon carbide single crystal 1 described above may be cut for use as seed crystal 2, and this seed crystal 2 may be used to grow silicon carbide single crystal 1 again on first main surface 2a of this seed crystal 2. As a result, dimension D1 in a direction perpendicular to the growth direction of silicon carbide single crystal 1 can be increased each time the crystal growth is performed.

In the step of growing silicon carbide single crystal 1 on first main surface 2a of seed crystal 2, silicon carbide source material 3 is heated while a small range is maintained for a temperature distribution in a source material region R1 where silicon carbide source material 3 is disposed. Specifically, silicon carbide source material 3 is sublimated while a temperature gradient between any two points in silicon carbide source material 3 is maintained at 30° C./cm or less. More specifically, silicon carbide single crystal 1 is grown on first main surface 2a of seed crystal 2 while the temperature of silicon carbide source material 3 is adjusted such that a temperature gradient between any two points in silicon carbide source material 3 in a plane parallel to surface 3a of silicon carbide source material 3 is 30° C./cm or less, and a temperature gradient between any two points in silicon carbide source material 3 in a plane perpendicular to surface 3a of silicon carbide source material 3 is 30° C./cm or less. The temperature gradient in silicon carbide source material 3 can be established, for example, by adjusting the thickness of a heat insulating material covering the crucible, or by changing the arrangement of the heating unit. Preferably, the temperature gradient between any two points in silicon carbide source material 3 in the step of growing the silicon carbide single crystal is 25° C./cm or less, more preferably 20° C. or less, and still more preferably 15° C. or less.

Preferably, in the step of growing silicon carbide single crystal 1, seed crystal 2 and silicon carbide source material 3 are heated such that a temperature gradient in a direction perpendicular to first main surface 2a of seed crystal 2 in source material region R1 is 30° C./cm or less, and a temperature gradient in the direction perpendicular to first main surface 2a of seed crystal 2 in a growth region R2 lying between surface 3a of silicon carbide source material 3 and a growth surface la of silicon carbide single crystal 1 facing surface 3a is 5° C./cm or more. The temperature gradient in the direction perpendicular to first main surface 2a of seed crystal 2 in growth region R2 is about 10° C./cm, for example.

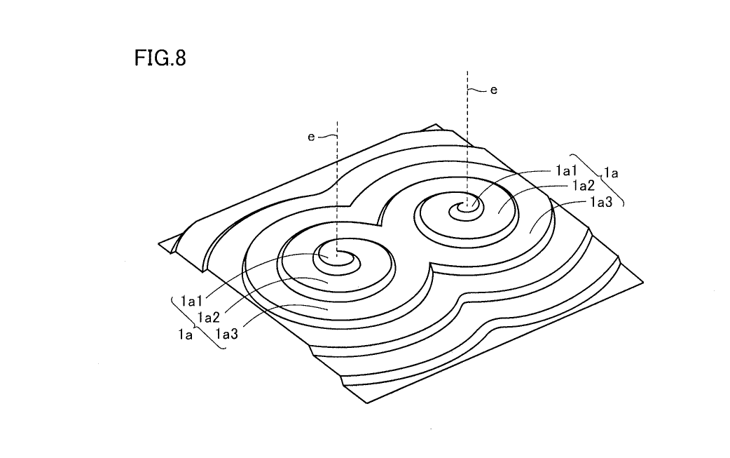

Referring to FIGS. 7 and 8, a growth mechanism of silicon carbide single crystal 1 is described. As shown in FIG. 7, growth surface 1a of silicon carbide single crystal 1 consists of a facet portion R3 and a non-facet portion R4. Silicon carbide single crystal 1 is grown in such an order that facet portion R3 reflecting the crystal structure of first main surface 2a of seed crystal 2 is formed first, and then non-facet portion R4 is formed. Silicon carbide single crystal 1 grows such that the crystal structure of facet portion R3 is transferred to non-facet portion R4. In facet portion R3, as shown in FIG. 8, steps 1a1, 1a2 and 1a3 are formed like screw stairs around a dislocation line e of screw dislocation exposed at growth surface 1a. In facet portion R3, the silicon carbide single crystal grows via spiral growth with the screw dislocation as a supply source of the steps. In non-facet portion R4, the silicon carbide single crystal grows via step-flow growth. In this manner, silicon carbide single crystal 1 grows on first main surface 2a of seed crystal 2.

Next, a slicing step (S30: FIG. 4) is performed. Specifically, after silicon carbide single crystal 1 is removed from the crucible, silicon carbide single crystal 1 is sliced by a wire saw, for example. Silicon carbide single crystal 1 is sliced along a plane intersecting the normal of first main surface 2a of seed crystal 2, for example. In this manner, silicon carbide single-crystal substrate 10 shown in FIGS. 1 to 3 is provided.

A function and effect of the silicon carbide single-crystal substrate and the method of manufacturing the same according to this embodiment will now be described.

According to the method of manufacturing silicon carbide single-crystal substrate 10 of this embodiment, silicon carbide single crystal 1 is grown on main surface 2a by sublimating silicon carbide source material 3 while maintaining a temperature gradient between any two points in silicon carbide source material 3 at 30° C./cm or less. Main surface 2a has a screw dislocation density of 20/cm² or more. This allows the manufacture of silicon carbide single-crystal substrate 10 in which the {0001} plane orientation difference between any two points spaced apart from each other by 1 cm in main surface 10a is 35 seconds or less, in which the mixture of a different polytype can be suppressed, and in which main surface 10a has a maximum dimension of 100 mm or more. Moreover, by employing the {0001} plane or a plane having an off angle of 10° or less relative to the {0001} plane as main surface 2a of seed crystal 2, the mixture of a stacking fault in silicon carbide single crystal 1 can be suppressed.

Further, according to the method of manufacturing silicon carbide single-crystal substrate 10 of this embodiment, main surface 2a has a screw dislocation density of 100000/cm² or less. Thus, the screw dislocation density in main surface 10a of silicon carbide single-crystal substrate 10 can be lowered.

Further, according to the method of manufacturing silicon carbide single-crystal substrate 10 of this embodiment, in the step of growing silicon carbide single crystal 1, the temperature gradient between surface 3a of silicon carbide source material 3 and growth surface 1a of silicon carbide single crystal 1 facing surface 3a of silicon carbide source material 3 is 5° C./cm or more. Thus, a growth rate of silicon carbide single crystal 1 can be improved.

Further, according to the method of manufacturing silicon carbide single-crystal substrate 10 of this embodiment, main surface 2a of seed crystal 2 has a maximum dimension of 80 mm or more, the cut surface of silicon carbide single crystal 1 sliced along a plane parallel to main surface 2a has a maximum dimension of 100 mm or more, and the maximum dimension of the cut surface of silicon carbide single crystal 1 is greater than the maximum dimension of main surface 2a of seed crystal 2. This allows the manufacture of silicon carbide single-crystal substrate 10 including main surface 10a having a great dimension.

According to silicon carbide single-crystal substrate 10 of this embodiment, main surface 10a has a maximum dimension of 100 mm or more. The {0001} plane orientation difference between any two points spaced apart from each other by 1 cm in first main surface 10a is 35 seconds or less. Thus, silicon carbide single-crystal substrate 10 in which main surface 10a has a maximum dimension of 100 mm or more, and which has an excellent crystal quality can be provided.

According to silicon carbide single-crystal substrate 10 of this embodiment, main surface 10a has a screw dislocation density of 20/cm² or more and 100000/cm² or less. Thus, silicon carbide single-crystal substrate 10 having a lowered screw dislocation density in main surface 10a can be provided.

### EXAMPLES

First, seed crystals 2 having a screw dislocation density of 5/cm², 15/cm², 20/cm², 500/cm² and 1000/cm² in first main surface 10a, respectively, were prepared. First main surface 2a of each seed crystal 2 had an off angle of 0° C. Each of seed crystals 2 described above was used to grow silicon carbide single crystal 1 on first main surface 2a of seed crystal 2 by sublimation. Silicon carbide single crystal 1 was grown with the method described in the embodiment above. Specifically, seed crystal 2 and silicon carbide source material 3 were placed in the crucible, and the temperature of the crucible was raised from ordinary temperature to 2300°. After the temperature of the crucible reached a temperature of 2300°, the pressure in the crucible was lowered to about 1 kPa, causing sublimation of silicon carbide source material 3 to grow silicon carbide single crystal 1 on first main surface 2a of seed crystal 2. The growth of silicon carbide single crystal 1 was completed in about 100 hours.

Dimension D2 of first main surface 2a of seed crystal 2 used in the first growth of the silicon carbide single crystal was set to 25.4 mm (1 inch). Dimension D1 in the direction perpendicular to the growth direction of silicon carbide single crystal 1 after being grown for 100 hours was greater than dimension D2 of first main surface 2a of seed crystal 2 by about 10 mm. Then, silicon carbide single crystal 1 thus grown was sliced for use as seed crystal 2 in the next crystal growth of silicon carbide single crystal 1. This seed crystal 2 was used to conduct a second crystal growth of silicon carbide single crystal 1. By using silicon carbide single crystal 1 having an increased dimension owing to the crystal growth of silicon carbide single crystal 1 as seed crystal 2 in the next crystal growth of silicon carbide single crystal 1 in this manner, dimension D1 of silicon carbide single crystal 1 was increased in increments of 10 mm, and the crystal growth of silicon carbide single crystal 1 was repeated until dimension D1 of silicon carbide single crystal 1 reached 100 mm.

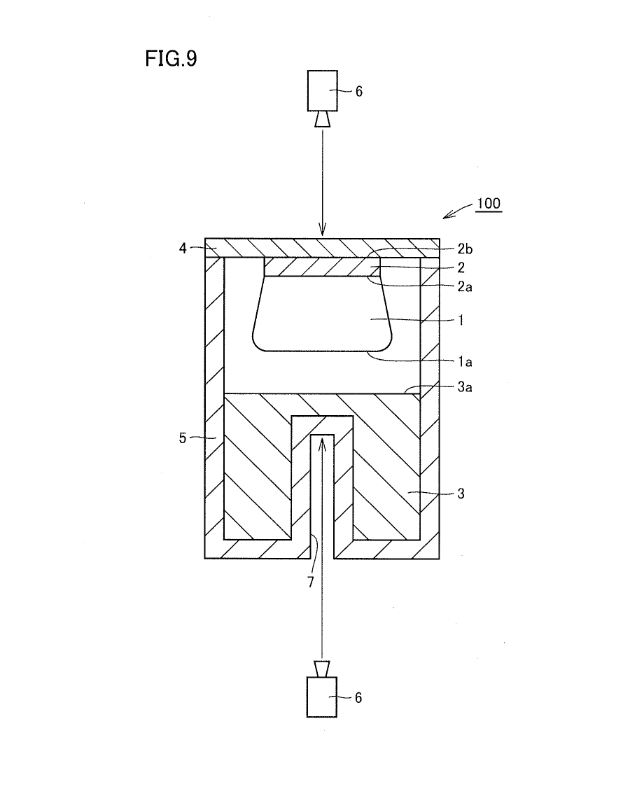

The temperature gradient in silicon carbide source material 2 when growing silicon carbide single crystal 1 on first main surface 2a of seed crystal 2 having each of the screw dislocation densities was set to 15° C./cm or less, 25° C./cm or less, 35° C./cm or less, and 45° C./cm or less. The temperature gradient in silicon carbide source material 3 was measured in a following manner. First, as shown in FIGS. 9 to 12, silicon carbide single crystal 1 was grown on first main surface 2a of seed crystal 2 by using four crucibles having different shapes of source material containing unit 5. The temperature of silicon carbide source material 3 was measured with a radiation thermometer 6 during the growth of silicon carbide single crystal 1. As shown in FIG. 9, a crucible having a recess in the vicinity of the center of source material containing unit 5, the bottom of the recess located in the vicinity of surface 3a of silicon carbide source material 3, was prepared. The temperature of silicon carbide source material 3 in the vicinity of the center of surface 3a of silicon carbide source material 3 was measured using this crucible.

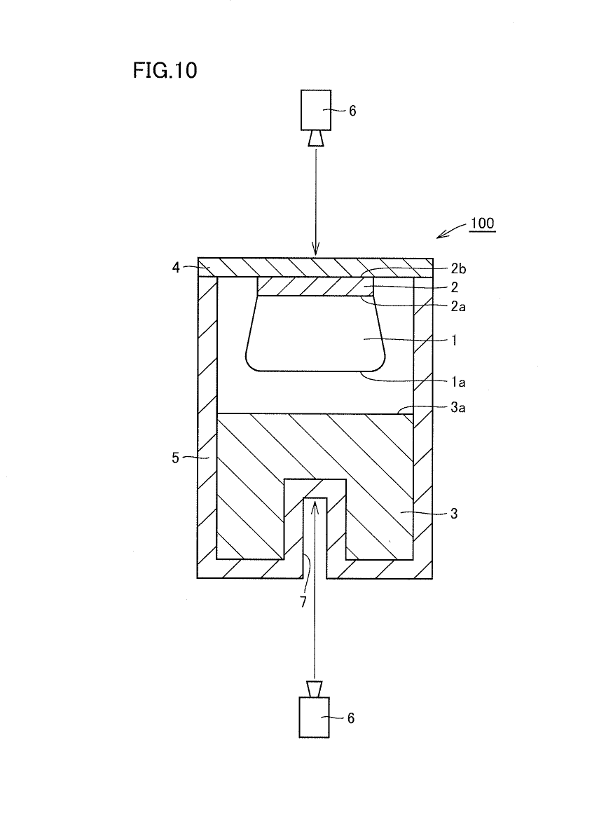

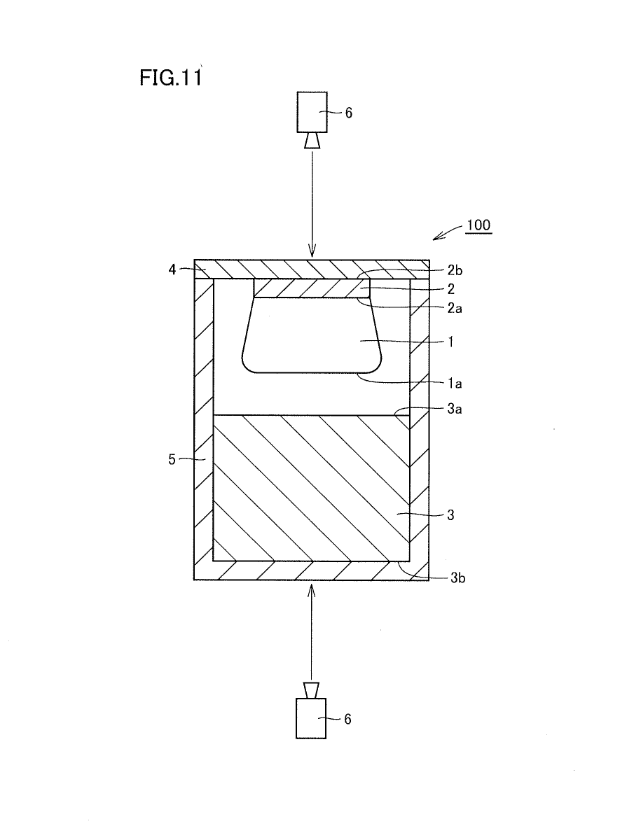

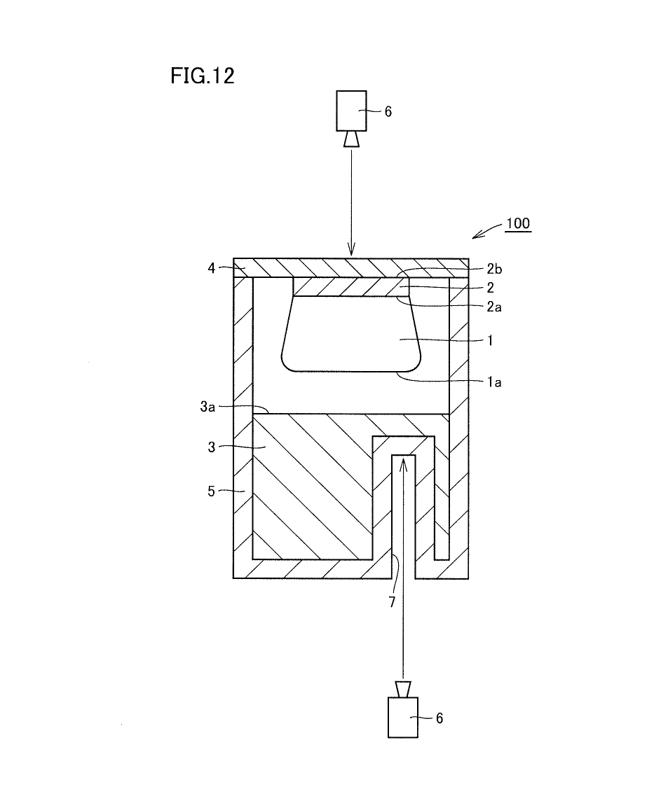

Next, as shown in FIG. 10, a crucible having a recess in the vicinity of the center of source material containing unit 5, the bottom of the recess located in the vicinity of the center in a normal direction of surface 3a of silicon carbide source material 3, was prepared. The temperature of silicon carbide source material 3 in the vicinity of the center of surface 3a of silicon carbide source material 3 as well as in the vicinity of the center in the normal direction of surface 3a was measured using this crucible. Next, as shown in FIG. 11, a crucible without a recess in source material containing unit 5 was prepared. The temperature of silicon carbide source material 3 in the vicinity of the center of rear surface 3b of silicon carbide source material 3 was measured using this crucible. Next, as shown in FIG. 12, a crucible having a recess close to the periphery of source material containing unit 5, the bottom of the recess located in the vicinity of surface 3a of silicon carbide source material 3, was prepared. The temperature of silicon carbide source material 3 in the vicinity of the periphery of surface 3a of silicon carbide source material 3 was measured using this crucible.

The temperatures of silicon carbide source material 3 measured using the crucibles shown in FIGS. 9, 10 and 11 were compared to one another, to measure the temperature gradient in silicon carbide source material 3 along the normal direction of surface 3a. In addition, the temperatures of silicon carbide source material 3 measured using the crucibles shown in FIGS. 9 and 12 were compared to each other, to measure the temperature gradient in silicon carbide source material 3 along an in-plane direction of surface 3a of silicon carbide source material 3. Heating conditions of the crucible were adjusted to determine heating conditions where the temperature gradient in silicon carbide source material 3 becomes equal to or lower than a desired value in each of the in-plane direction and the normal direction of the surface of silicon carbide source material 3.

Next, silicon carbide single crystal 1 grown at each of the screw dislocation densities described above and each of the temperature gradients in the silicon carbide source material described above was sliced into silicon carbide single-crystal substrate 10. A plane orientation at each of any two points spaced apart from each other by 1 cm in main surface 10a of silicon carbide single-crystal substrate 10 was measured, and the plane orientation difference between the two points was calculated. The plane orientation was measured with the method described in the embodiment above. Specifically, the plane orientation was measured via X-ray diffraction. Cu-Kα1 was used, for example, as an X-ray source, and (0004) peak was measured. A wavelength was 1.5405 angstroms (monochromatization).

Referring to Table 1, the plane orientation difference in main surface 10a of silicon carbide single-crystal substrate 10 when first main surface 2a of seed crystal 2 had an off angle of 0° is described.

TABLE 1

Temperature Gradient (° C./cm)

| | | | | |
|---|---|---|---|---|
| Off Angle: 0 degree | 15 | 25 | 35 | 45 |

| | | | | | |
|---|---|---|---|---|---|
| Seed Crystal | 5 | 50 | 74 | 148 | 248 |
| Dislocation | 15 | 40 | 38 | 71 | 105 |
| Density | 20 | 17 | 25 | 68 | 98 |
| (/cm²) | 500 | 16 | 19 | 67 | 91 |
| | 1000 | 18 | 32 | 42 | 75 |

[Unit: Second]

As shown in Table 1, when first main surface 2a of seed crystal 2 had a screw dislocation density of 20/cm² or more and silicon carbide source material 3 had a temperature gradient of 30° C./cm or less, the plane orientation difference between the two points spaced apart from each other by 1 cm in main surface 10a of silicon carbide single-crystal substrate 10 was 32 seconds or less. On the other hand, when first main surface 2a of seed crystal 2 had a screw dislocation density of less than 20/cm², or when silicon carbide source material 3 had a temperature gradient of more than 30° C./cm, the plane orientation difference between the two points spaced apart from each other by 1 cm in main surface 10a of silicon carbide single-crystal substrate 10 was 38 seconds or more.

Next, seed crystals 2 in which first main surface 2a of seed crystal 2 had an off angle of 4°, and first main surface 10a had a screw dislocation density of 5/cm², 15/cm², 20/cm², 500/cm² and 1000/cm², respectively, were prepared. In addition, seed crystals 2 in which first main surface 2a of seed crystal 2 had an off angle of 10°, and first main surface 10a had a screw dislocation density of 5/cm², 15/cm², 20/cm², 500/cm² and 1000/cm², respectively, were prepared. Further, seed crystals 2 in which first main surface 2a of seed crystal 2 had an off angle of 15°, and first main surface 10a had a screw dislocation density of 5/cm², 15/cm², 20/cm², 500/cm² and 1000/cm², respectively, were prepared.

Each of seed crystals 2 described above was used to grow silicon carbide single crystal 1 on first main surface 2a of seed crystal 2 by sublimation in a manner similar to that when the off angle was 0°. The temperature gradient in silicon carbide source material 2 when growing silicon carbide single crystal 1 on first main surface 2a of each of seed crystals 2 described above was set to 15° C./cm or less, 25° C./cm or less, 35° C./cm or less, and 45° C./cm or less. Silicon carbide single crystal 1 grown at each of the off angles described above, each of the screw dislocation densities described above and each of the temperature gradients in the silicon carbide source material described above was sliced into silicon carbide single-crystal substrate 10. A plane orientation at each of any two points spaced apart from each other by 1 cm in main surface 10a of silicon carbide single-crystal substrate 10 was measured, and the plane orientation difference between the two points was calculated.

Referring to Table 2, the plane orientation difference in main surface 10a of silicon carbide single-crystal substrate 10 when first main surface 2a of seed crystal 2 had an off angle of 4° is described.

TABLE 2

Temperature Gradient (° C./cm)

| Off Angle: 4 degrees | | 15 | 25 | 35 | 45 |
|---|---|---|---|---|---|
| Seed Crystal | 5 | 45 | 50 | 77 | 127 |
| Dislocation | 15 | 40 | 38 | 39 | 56 |
| Density | 20 | 12 | 16 | 37 | 52 |
| (/cm²) | 500 | 11 | 13 | 37 | 49 |
| | 1000 | 12 | 19 | 45 | 41 |

[Unit: Second]

As shown in Table 2, when first main surface 2a of seed crystal 2 had a screw dislocation density of 20/cm² or more and silicon carbide source material 3 had a temperature gradient of 30° C./cm or less, the plane orientation difference between the two points spaced apart from each other by 1 cm in main surface 10a of silicon carbide single-crystal substrate 10 was 19 seconds or less. On the other hand, when first main surface 2a of seed crystal 2 had a screw dislocation density of less than 20/cm², or when silicon carbide source material 3 had a temperature gradient of more than 30° C./cm, the plane orientation difference between the two points spaced apart from each other by 1 cm in main surface 10a of silicon carbide single-crystal substrate 10 was 38 seconds or more.

Referring to Table 3, the plane orientation difference in main surface 10a of silicon carbide single-crystal substrate 10 when first main surface 2a of seed crystal 2 had an off angle of 10° is described.

TABLE 3

Temperature Gradient (° C./cm)

| Off Angle: 10 degrees | | 15 | 25 | 35 | 45 |
|---|---|---|---|---|---|
| Seed Crystal | 5 | 53 | 58 | 85 | 135 |
| Dislocation | 15 | 40 | 38 | 47 | 64 |
| Density | 20 | 20 | 24 | 45 | 60 |
| (/cm²) | 500 | 19 | 21 | 45 | 57 |
| | 1000 | 20 | 27 | 53 | 49 |

[Unit: Second]

As shown in Table 3, when first main surface 2a of seed crystal 2 had a screw dislocation density of 20/cm² or more and silicon carbide source material 3 had a temperature gradient of 30° C./cm or less, the plane orientation difference between the two points spaced apart from each other by 1 cm in main surface 10a of silicon carbide single-crystal substrate 10 was 27 seconds or less. On the other hand, when first main surface 2a of seed crystal 2 had a screw dislocation density of less than 20/cm², or when silicon carbide source material 3 had a temperature gradient of more than 30° C./cm, the plane orientation difference between the two points spaced apart from each other by 1 cm in main surface 10a of silicon carbide single-crystal substrate 10 was 38 seconds or more.

Referring to Table 4, the plane orientation difference in main surface 10a of silicon carbide single-crystal substrate 10 when first main surface 2a of seed crystal 2 had an off angle of 15° is described.

TABLE 4

Temperature Gradient (° C./cm)

| Off Angle: 15 degrees | | 15 | 25 | 35 | 45 |
|---|---|---|---|---|---|
| Seed Crystal | 5 | 69 | 75 | 111 | 176 |
| Dislocation | 15 | 40 | 38 | 60 | 83 |
| Density | 20 | 25 | 31 | 59 | 78 |
| (/cm²) | 500 | 25 | 27 | 58 | 73 |
| | 1000 | 26 | 35 | 69 | 63 |

[Unit: Second]

As shown in Table 4, when first main surface 2a of seed crystal 2 had a screw dislocation density of 20/cm² or more and silicon carbide source material 3 had a temperature gradient of 30° C./cm or less, the plane orientation difference between the two points spaced apart from each other by 1 cm in main surface 10a of silicon carbide single-crystal substrate 10 was 35 seconds or less. On the other hand, when first main surface 2a of seed crystal 2 had a screw dislocation density of less than 20/cm², or when silicon carbide source material 3 had a temperature gradient of more than 30° C./cm, the plane orientation difference between the two points spaced apart from each other by 1 cm in main surface 10a of silicon carbide single-crystal substrate 10 was 38 seconds or more. It is noted that, only when first main surface 2a of seed crystal 2 had an off angle of 15°, the mixture of a stacking fault was confirmed in silicon carbide single-crystal substrates 10 manufactured under all combination conditions of the screw dislocation densities and temperature gradients described above. Put another way, the mixture of a stacking fault in silicon carbide single-crystal substrate 10 could be suppressed when first main surface 2a of seed crystal 2 had an off angle of 10° or less.

Next, it was confirmed whether the mixture of a different polytype was observed or not in silicon carbide single-crystal substrates 10 manufactured under conditions of each of the off angles described above (0°, 4°, 10° and 15°), each of the screw dislocation densities described above (5/cm², 15/cm², 20/cm², 500/cm² and 1000/cm²), and each of the temperature gradients described above (15° C./cm or less, 25° C./cm or less, 35° C./cm or less, and 45° C./cm or less). The confirmation of whether a different polytype was mixed or not was made by visually observing a wafer and determining whether there is a region of a different color or not.

Referring to Tables 5 to 8, the mixture of a different polytype in silicon carbide single-crystal substrates 10 is described. Table 5, Table 6, Table 7 and Table 8 show the results when first main surface 2a of seed crystal 2 had an off angle of 0°, 4°, 10° and 15°, respectively. In Tables 5 to 8, a symbol “A” indicates that the mixture of a different polytype in silicon carbide single-crystal substrate 10 was not observed during a process of increasing the dimension of silicon carbide single crystal 1 from 25.4 mm to 100 mm, while a symbol “B” indicates that the mixture of a different polytype in silicon carbide single-crystal substrate 10 was observed during the process of increasing the dimension of silicon carbide single crystal 1 from 25.4 mm to 100 mm. Put another way, this means that the silicon carbide single-crystal substrate in which the main surface had a maximum dimension of 100 mm or more and in which a different polytype was not mixed could be obtained under conditions of the symbol “A”, while the silicon carbide single-crystal substrate in which the main surface had a maximum dimension of 100 mm or more and in which a different polytype was not mixed could not be obtained under conditions of the symbol “B”.

TABLE 5

Temperature Gradient (° C./cm)

| | | | | |
|---|---|---|---|---|
| Off Angle: 0 degree | 15 | 25 | 35 | 45 |

| | | | | | |
|---|---|---|---|---|---|
| Seed Crystal | 5 | B | B | B | B |
| Dislocation | 15 | B | B | B | B |
| Density | 20 | A | A | A | A |
| (/cm²) | 500 | A | A | A | A |
| | 1000 | A | A | A | A |

TABLE 6

Temperature Gradient (° C./cm)

| Off Angle: 4 degrees | | 15 | 25 | 35 | 45 |
|---|---|---|---|---|---|
| Seed Crystal | 5 | B | B | B | B |
| Dislocation | 15 | B | B | B | B |
| Density | 20 | A | A | A | A |
| (/cm²) | 500 | A | A | A | A |
| | 1000 | A | A | A | A |

TABLE 7

Temperature Gradient (° C./cm)

| Off Angle: 10 degrees | | 15 | 25 | 35 | 45 |
|---|---|---|---|---|---|
| Seed Crystal | 5 | B | B | B | B |
| Dislocation | 15 | B | B | B | B |
| Density | 20 | A | A | A | A |
| (/cm²) | 500 | A | A | A | A |
| | 1000 | A | A | A | A |

TABLE 8

Temperature Gradient (° C./cm)

| Off Angle: 15 degrees | | 15 | 25 | 35 | 45 |
|---|---|---|---|---|---|
| Seed Crystal | 5 | B | B | B | B |
| Dislocation | 15 | B | B | B | B |
| Density | 20 | A | A | A | A |
| (/cm²) | 500 | A | A | A | A |
| | 1000 | A | A | A | A |

As shown in Tables 5 to 8, in all of the cases where first main surface 2a of seed crystal 2 had an off angle of 0°, 4°, 10° and 15°, regardless of the temperature gradient in silicon carbide source material 3, silicon carbide single-crystal substrate 10 in which a different polytype was not mixed and in which main surface 10a had a maximum dimension of 100 mm or more could be obtained under conditions where first main surface 2a of seed crystal 2 had a screw dislocation density of 20/cm² or more. On the other hand, in all of the cases where first main surface 2a of seed crystal 2 had an off angle of 0°, 4°, 10° and 15°, regardless of the temperature gradient in silicon carbide source material 3, the mixture of a different polytype in silicon carbide single-crystal substrate 10 was observed under conditions where first main surface 2a of seed crystal 2 had a screw dislocation density of less than 20/cm². In other words, under conditions where the screw dislocation density was less than 20/cm², silicon carbide single-crystal substrate 10 in which a different polytype was not mixed and in which main surface 10a had a maximum dimension of 100 mm or more could not be obtained. From the above results, it was confirmed that when first main surface 2a of seed crystal 2 had a screw dislocation density of 20/cm² or more and silicon carbide source material 3 had a temperature gradient of 30° C./cm or less, the plane orientation difference between two points spaced apart from each other by 1 cm in main surface 10a of silicon carbide single-crystal substrate 10 manufactured under this screw dislocation density condition, and this temperature gradient condition was 35 seconds or less. In addition, when first main surface 2a of seed crystal 2 had an off angle of 10° or less, the mixture of a stacking fault in silicon carbide single-crystal substrate 10 was not observed. Further, when first main surface 2a of seed crystal 2 had a screw dislocation density of 20/cm² or more, silicon carbide single-crystal substrate 10 in which the mixture of a different polytype was suppressed and in which main surface 10a had a maximum dimension of 100 mm or more could be obtained.

It should be understood that the embodiments and examples disclosed herein are illustrative and non-restrictive in every respect. The scope of the present invention is defined by the terms of the claims, rather than the description above, and is intended to include any modifications within the scope and meaning equivalent to the terms of the claims.

### REFERENCE SIGNS LIST

1 silicon carbide single crystal; 1a growth surface; 2 seed crystal; 2a main surface (first main surface): 2b second main surface; 3 silicon carbide source material; 3a surface; 3b rear surface; 4 seed crystal holding unit; 5 source material containing unit; 6 radiation thermometer; 10 silicon carbide single-crystal substrate; 100 manufacturing device; D1, D2 dimension; R1 source material region; R2 growth region; R3 facet portion; R4 non-facet portion; S1 first spot; S2 second spot; a1, a2 position; c1, c2 plane orientation; d1, d2 spot diameter; e dislocation line; n normal direction.

1. A method of manufacturing a silicon carbide single-crystal substrate, comprising the steps of:
preparing a seed crystal having a main surface and being made of silicon carbide, and a silicon carbide source material; and
growing a silicon carbide single crystal on said main surface by sublimating said silicon carbide source material while maintaining a temperature gradient between any two points in said silicon carbide source material at 30° C./cm or less,
said main surface of said seed crystal being a {0001} plane or a plane having an off angle of 10° or less relative to the {0001} plane, said main surface having a screw dislocation density of 20/cm² or more.

2. The method of manufacturing a silicon carbide single-crystal substrate according to claim 1, wherein
said main surface has a screw dislocation density of 100000/cm² or less.

3. The method of manufacturing a silicon carbide single-crystal substrate according to claim 1, wherein
in said step of growing a silicon carbide single crystal, a temperature gradient between a surface of said silicon carbide source material and a growth surface of said silicon carbide single crystal facing said surface of said silicon carbide source material is 5° C./cm or more.

4. The method of manufacturing a silicon carbide single-crystal substrate according to claim 1, wherein
said main surface of said seed crystal has a maximum dimension of 80 mm or more, and a cut surface of said silicon carbide single crystal sliced along a plane parallel to said main surface has a maximum dimension of 100 mm or more, and
the maximum dimension of said cut surface of said silicon carbide single crystal is greater than the maximum dimension of said main surface of said seed crystal.

5. A silicon carbide single-crystal substrate comprising a main surface,
said main surface having a maximum dimension of 100 mm or more,
a {0001} plane orientation difference between any two points spaced apart from each other by 1 cm in said main surface being 35 seconds or less.

6. The silicon carbide single-crystal substrate according to claim 5, wherein
said main surface has a screw dislocation density of 20/cm² or more and 100000/cm² or less.
